(19) United States
(12) Patent Application Publication
(10) Pub. No.: US 2026/0319001 A1
(43) Pub. Date: Oct. 15, 2026

(54) BATTERY CAPACITY DETERMINATION METHOD AND BATTERY STATE-OF-HEALTH DETERMINATION METHOD

(71) Applicant: BYD COMPANY LIMITED, Shenzhen (CN)

(72) Inventors: Tianyu FENG, Shenzhen (CN); Xiaoqian LI, Shenzhen (CN); Huili CAO, Shenzhen (CN)

(73) Assignee: BYD COMPANY LIMITED, Shenzhen (CN)

(21) Appl. No.: 19/704,366

(22) Filed: Jun. 10, 2026

Related U.S. Application Data
(63) Continuation of application No. PCT/CN2024/110204, filed on Aug. 6, 2024.

(30) Foreign Application Priority Data
Dec. 15, 2023 (CN) 202311738482.6

(51) Int. Cl. G01R 31/3835; G01R 19/165; G01R 31/367; G01R 31/392

(52) U.S. Cl. CPC G01R 31/3835; G01R 19/16542; G01R 31/367; G01R 31/392

(57) ABSTRACT

In a battery capacity determination method, when an initial static voltage of a battery at which a charging operation starts is less than or equal to a preset voltage threshold value, a current high-voltage inflection point capacity of the battery is determined based on an initial residual capacity corresponding to the initial static voltage and a first capacity corresponding to a charge transferred into the battery from the initial static voltage to a high-voltage inflection point during the charging operation. In the method, a current maximum capacity of the battery is determined based on the current high-voltage inflection point capacity. Apparatus and non-transitory computer-readable storage medium counterparts are also contemplated.

### CROSS-REFERENCE TO RELATED APPLICATIONS

The present application is a continuation of International Application No. PCT/CN2024/110204, filed on Aug. 6, 2024, which claims priority to Chinese Patent Application No. 202311738482.6, filed on Dec. 15, 2023. The entire disclosures of the prior applications are hereby incorporated by reference.

### TECHNICAL FIELD

The present disclosure relates to the field of new energy, including a battery capacity determination method, a battery state-of-health determination method, a computer program product, a processor, a power distribution box, a battery management system (BMS), and an electrical apparatus.

### BACKGROUND

With the rapid development of the automotive industry, new energy vehicles have gradually become more widely used. Compared with other automobiles, new energy vehicles such as electric vehicles emit fewer harmful substances. The power source of an electric vehicle is a battery, which can convert chemical energy into electrical energy to drive a motor to operate the vehicle. The state-of-health (SOH) of the battery is an important parameter for measuring the safety, reliability, and power performance of an electric vehicle.

In some scenarios, the battery capacity may be calculated by determining the high-voltage inflection point of the charging curve of the battery in offline data. However, as the battery cells may have initial differences or may age differently, the high-voltage inflection point of the battery charging curve may vary. Therefore, calculating the battery capacity using offline battery data may result in erroneous measurements.

### SUMMARY

The present disclosure addresses at least one technical problem in the related technology. To this end, the present disclosure includes a battery capacity determination method, which has the advantage of improving the accuracy of battery capacity.

According to a first aspect of an embodiment of the present disclosure, the present disclosure includes a battery capacity determination method. In the method, when an initial static voltage of a battery at which a charging operation starts is less than or equal to a preset voltage threshold value, a current high-voltage inflection point capacity of the battery is determined based on an initial residual capacity corresponding to the initial static voltage and a first capacity corresponding to a charge transferred into the battery from the initial static voltage to a high-voltage inflection point during the charging operation. In the method, a current maximum capacity of the battery is determined based on the current high-voltage inflection point capacity.

According to a second aspect of an embodiment of the present disclosure, the present disclosure includes a battery capacity determination apparatus. The battery capacity determination apparatus includes processing circuitry configured to, when an initial static voltage of a battery at which a charging operation starts is less than or equal to a preset voltage threshold value, determine a current high-voltage inflection point capacity of the battery based on an initial residual capacity corresponding to the initial static voltage and a first capacity corresponding to a charge transferred into the battery from the initial static voltage to the high-voltage inflection point during the charging operation. The processing circuitry is configured to determine a current maximum capacity of the battery based on the current high-voltage inflection point capacity.

According to a third aspect of an embodiment of the present disclosure, the present disclosure includes a non-transitory computer-readable storage medium. The non-transitory computer-readable storage medium stores instructions which, when executed by a processor, cause the processor to perform a battery capacity determination method. In the method, when an initial static voltage of a battery at which a charging operation starts is less than or equal to a preset voltage threshold value, a current high-voltage inflection point capacity of the battery is determined based on an initial residual capacity corresponding to the initial static voltage and a first capacity corresponding to a charge transferred into the battery from the initial static voltage to a high-voltage inflection point during the charging operation. In the method, a current maximum capacity of the battery is determined based on the current high-voltage inflection point capacity.

According to a fourth aspect of an embodiment of the present disclosure, a battery capacity determination method includes: when an initial static voltage of a battery from which charging starts is less than or equal to a preset voltage threshold value, according to an initial residual capacity corresponding to the initial static voltage and a first capacity charged into the battery from the initial static voltage to a high-voltage inflection point, the high-voltage inflection point capacity of the battery being updated to obtain the current high-voltage inflection point capacity of the battery; and according to the current high-voltage inflection point capacity, a current maximum capacity of the battery being determined.

In an embodiment of the present disclosure, the high-voltage inflection point capacity of the battery being updated according to an initial residual capacity corresponding to the initial static voltage and a first capacity charged into the battery from the initial static voltage to a high-voltage inflection point includes: the initial residual capacity being obtained; a previous maximum capacity of the battery being obtained; and the current high-voltage inflection point capacity being determined according to the previous maximum capacity, the initial residual capacity, and the first capacity.

In an embodiment of the present disclosure, the current high-voltage inflection point capacity being determined according to the previous maximum capacity, the initial residual capacity, and the first capacity includes: a product of the previous maximum capacity and the initial residual capacity being calculated; a first sum of the product and the first capacity being calculated; and the first sum being taken as the current high-voltage inflection point capacity.

In an embodiment of the present disclosure, the current maximum capacity of the battery being determined according to the current high-voltage inflection point capacity includes: a second capacity charged into the battery from the high-voltage inflection point to full charge being obtained; and the current maximum capacity being determined according to the second capacity and the current high-voltage inflection point capacity.

In an embodiment of the present disclosure, the method further includes:
when the initial static voltage is greater than the preset voltage threshold, the current maximum capacity being determined according to a previous high-voltage inflection point capacity of the battery.

In an embodiment of the present disclosure, before updating the high-voltage inflection point capacity of the battery according to the initial residual capacity corresponding to the initial static voltage and the first capacity charged into the battery from the initial static voltage to the high-voltage inflection point to obtain the current high-voltage inflection point capacity of the battery, the method further includes: a voltage-capacity curve of the battery being obtained during a charging operation; a filtered voltage-capacity curve being obtained by performing smoothing filtering on the voltage-capacity curve; a differential voltage-capacity curve being obtained by performing a differential operation on the voltage-capacity curve; and the high-voltage inflection point being determined based on a peak value of the differential voltage-capacity curve.

In an embodiment of the present disclosure, the high-voltage inflection point being determined according to the peak value includes: a peak voltage corresponding to the peak value being obtained from the voltage-capacity curve; a maximum value of the peak voltage being determined; and the maximum value being taken as the high-voltage inflection point.

According to a fifth aspect of an embodiment of the present disclosure, a battery state-of-health determination method applied to the battery capacity determination method according to one or more aspects of this disclosure includes: a current maximum capacity of a battery being determined by a battery capacity determination method according to one or more aspects of this disclosure; and a state-of-health of the battery being determined according to a ratio of the current maximum capacity to an initial capacity of the battery.

According to a sixth aspect of an embodiment of the present disclosure, a computer program product includes instructions that, when the computer program product runs on a computer, cause the computer to execute the battery capacity determination method according to one or more aspects of this disclosure or the battery state-of-health determination method according to one or more aspects of this disclosure.

According to a seventh aspect of an embodiment of the present disclosure, a processor is configured to execute instructions to implement the battery capacity determination method according to one or more aspects of this disclosure or the battery state-of-health determination method according to one or more aspects of this disclosure.

According to an eighth aspect of an embodiment of the present disclosure, a power distribution box includes the processor according to one or more aspects of this disclosure.

According to a ninth aspect of an embodiment of the present disclosure, a BMS system includes the power distribution box according to one or more aspects of this disclosure and/or includes the processor according to one or more aspects of this disclosure.

According to a tenth aspect of an embodiment of the present disclosure, an electrical apparatus includes the BMS system according to one or more aspects of this disclosure.

In the battery capacity determination method according to one or more embodiments of the present disclosure, when the initial static voltage of a battery from which charging starts is less than or equal to a preset voltage threshold value, a high-voltage inflection point capacity of the battery is updated according to an initial residual capacity corresponding to the initial static voltage and a first capacity charged into the battery from the initial static voltage to a high-voltage inflection point, thereby obtaining the current high-voltage inflection point capacity of the battery; the current maximum capacity of the battery is determined according to the current high-voltage inflection point capacity, avoiding the problem of large errors in calculating battery capacity using offline battery data, thereby improving the accuracy of battery capacity.

Additional aspects and advantages of the present disclosure will be set forth in part in the description which follows, and in part will be apparent from the description or may be learned by practice of the disclosure.

### BRIEF DESCRIPTION OF THE DRAWINGS

FIG. 1 is a flowchart of a battery capacity determination method according to an embodiment;

FIG. 2 is a schematic diagram of a voltage-capacity curve according to an embodiment;

FIG. 3 is a schematic diagram of a differential voltage-capacity curve according to an embodiment;

FIG. 4 is a flowchart of a battery state-of-health determination method according to an embodiment;

FIG. 5 is a schematic diagram of a computer program product according to an embodiment; and

FIG. 6 is a block diagram of an electrical apparatus according to an embodiment.

### DETAILED DESCRIPTION

Embodiments of the present disclosure are described below. Examples of one or more embodiments are shown in the accompanying drawings, wherein the same or similar reference numerals refer to the same or similar elements or elements having the same or similar functions throughout. One or more embodiments described below with reference to the accompanying drawings are provided to explain the present disclosure and should not be construed as limiting the present disclosure.

Descriptions of terms in this disclosure are provided as examples only and are not intended to limit the scope of the disclosure.

In this disclosure, the phrase “at least one of A, B, or C” is intended to include any one of A, B, or C and any combination of A, B, or C, and the phrase “one of A and B” is intended to include A, B, or both A and B, unless expressly stated otherwise.

A battery capacity determination method according to one or more embodiments of the present disclosure will be described below with reference to the accompanying drawings. Referring to FIG. 1, the battery capacity determination method may include the following steps:
S1. When an initial static voltage of a battery from which charging (for example, a charging operation) starts is less than or equal to a preset voltage threshold value, according to an initial residual capacity corresponding to the initial static voltage and a first capacity charged into the battery from the initial static voltage to a high-voltage inflection point, the high-voltage inflection point capacity of the battery is updated to obtain the current high-voltage inflection point capacity of the battery;
S2. According to the current high-voltage inflection point capacity, a current maximum capacity of the battery is determined.

In some examples, when an initial static voltage of a battery at which a charging operation starts is less than or equal to a preset voltage threshold value, a current high-voltage inflection point capacity of the battery is determined based on an initial residual capacity corresponding to the initial static voltage and a first capacity corresponding to a charge transferred into the battery from the initial static voltage to a high-voltage inflection point during the charging operation. In some examples, a current maximum capacity of the battery is determined based on the current high-voltage inflection point capacity.

In some aspects, in the battery capacity determination method according to one or more embodiments of the present disclosure, when the initial static voltage of a battery from which charging starts is less than or equal to a preset voltage threshold value, according to an initial residual capacity corresponding to the initial static voltage and a first capacity charged into the battery from the initial static voltage to a high-voltage inflection point, the high-voltage inflection point capacity of the battery is updated to obtain the current high-voltage inflection point capacity of the battery; according to the current high-voltage inflection point capacity, a current maximum capacity of the battery is determined, avoiding the problem of large errors in calculating battery capacity using offline battery data, thereby improving the accuracy of battery capacity.

Each step in the battery capacity determination method in one or more embodiments of the present disclosure will be described in further detail with reference to the accompanying drawings and embodiments.

In S1, when an initial static voltage of a battery from which charging starts is less than or equal to a preset voltage threshold value, according to an initial residual capacity corresponding to the initial static voltage and a first capacity charged into the battery from the initial static voltage to a high-voltage inflection point, the high-voltage inflection point capacity of the battery is updated to obtain the current high-voltage inflection point capacity of the battery.

How to determine the first capacity charged into the battery from the initial static voltage to the high-voltage inflection point is explained below.

In an embodiment of the present disclosure, the battery may be a lithium-ion battery. One or more embodiments of the present disclosure will be described below by taking a lithium iron phosphate lithium-ion battery, which is a type of lithium-ion battery, as an example.

In an embodiment of the present disclosure, after the lithium iron phosphate lithium-ion battery is discharged, it may be left to stand for a period of time, for example, two hours, and then charging of the lithium iron phosphate lithium-ion battery may be started, and the initial static voltage of the lithium iron phosphate lithium-ion battery may be obtained.

In an embodiment of the present disclosure, the smaller the measured static voltage of the lithium iron phosphate lithium-ion battery, the closer the capacity of the lithium iron phosphate lithium-ion battery calculated according to the voltage at this time may be to the actual capacity. Therefore, the obtained first capacity charged into the lithium iron phosphate lithium-ion battery from the initial static voltage to the high-voltage inflection point may also be more accurate, and further updating the current high-voltage inflection point capacity of the battery according to the first capacity may also be more accurate, thereby obtaining more accurate data. In an embodiment of the present disclosure, the charging duration and charging current when the lithium iron phosphate lithium-ion battery is charged from the initial static voltage to the high-voltage inflection point may be obtained, and then the ampere-hour integration method may be used to calculate the first capacity charged into the lithium iron phosphate lithium-ion battery from the initial static voltage to the high-voltage inflection point. The ampere-hour integration method uses a current-time accumulation method to estimate the state of charge of a dynamic lithium battery in real time. The calculation formula of the ampere-hour integration method is as follows:

$$SOC ( t ) = S O {C}_{0} + {\int }_{0}^{t} I ( t ) dt / CE \qquad ( 1 )$$

wherein SOC₀ is the initial value of the battery state of charge; CE is the rated capacity of the battery; I(t) is the charging/discharging current of the battery at time t; and t is the charging/discharging time. In some aspects, the ampere-hour integration method may be relatively less limited by the condition of the battery itself, and the calculation method may be simpler and more reliable, enabling real-time estimation of the state of charge of the battery.

How to determine the high-voltage inflection point of the lithium iron phosphate lithium-ion battery is explained below.

In an embodiment of the present disclosure, before updating the high-voltage inflection point capacity of the battery according to the initial residual capacity corresponding to the initial static voltage and the first capacity charged into the battery from the initial static voltage to the high-voltage inflection point to obtain the current high-voltage inflection point capacity of the battery, the method further includes:
S31. Obtaining a voltage-capacity curve of the battery during a charging operation;
S32. Obtaining a filtered voltage-capacity curve by performing smoothing filtering on the voltage-capacity curve;
S33. Obtaining a differential voltage-capacity curve by performing a differential operation on the voltage-capacity curve;

In some examples, a voltage-capacity curve of a lithium-ion battery during charging and discharging processes has an interval where the voltage changes relatively slowly, which is called a voltage plateau region. During the transition between two different plateau regions, there exists a point where the voltage changes fastest, called an inflection point. Three such voltage plateau regions may exist for a lithium iron phosphate battery, and two inflection points may be identified. Differentiated by voltage level, the inflection point with a higher voltage is marked as a high-voltage inflection point (HVTP), and the inflection point with a lower voltage is marked as a low-voltage inflection point (LVTP).

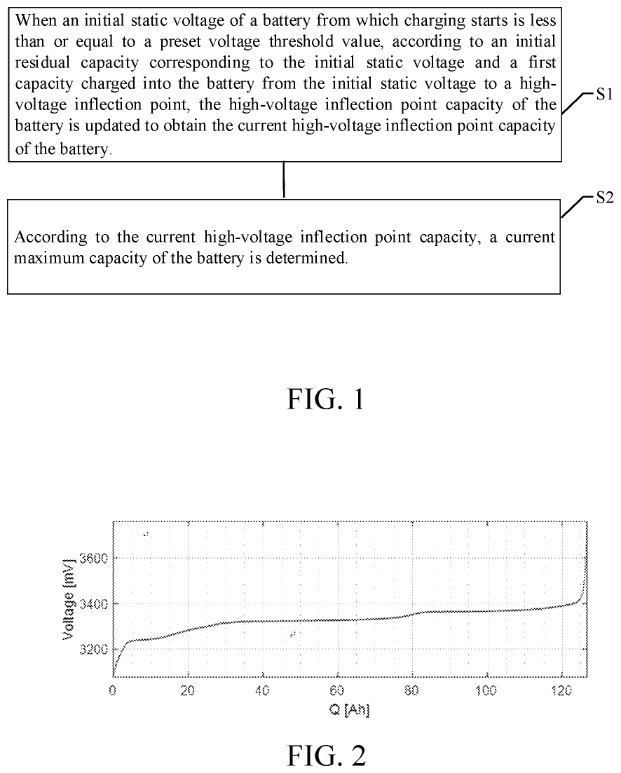

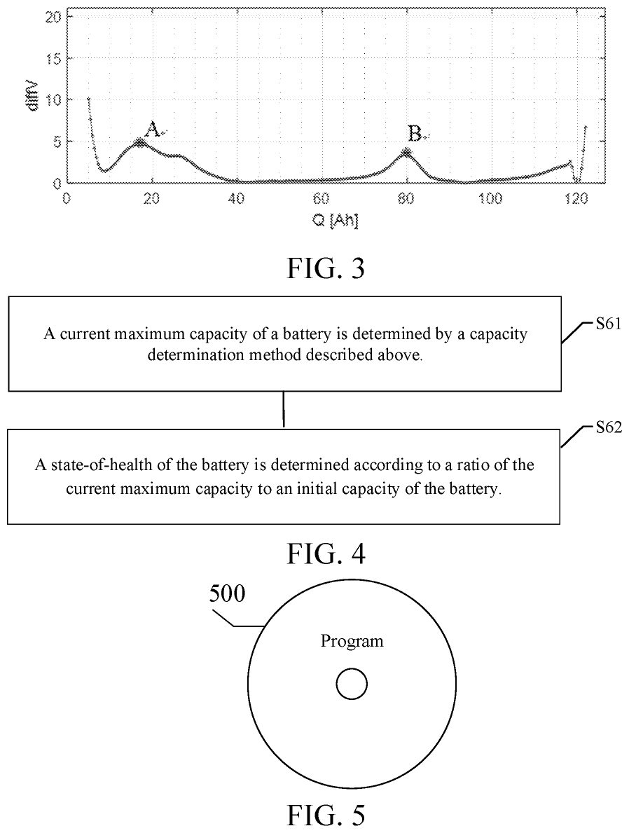

In an embodiment of the present disclosure, before the lithium iron phosphate lithium-ion battery leaves the factory, the lithium iron phosphate lithium-ion battery may be discharged to a cut-off voltage (SOC=0%), then the lithium iron phosphate lithium-ion battery is charged, and the voltage-capacity curve during the charging operation of the lithium iron phosphate lithium-ion battery is recorded. An example of the recorded voltage-capacity curve is shown in FIG. 2. Further, smoothing filtering is performed on the voltage-capacity curve to obtain a filtered voltage-capacity curve. Then, a differential of the voltage with respect to the capacity is calculated for the filtered voltage-capacity curve to obtain a differential voltage-capacity curve, such as the one shown in FIG. 3.
S34. Determining the high-voltage inflection point based on a peak value of the differential voltage-capacity curve.

In an embodiment of the present disclosure, a peak voltage corresponding to the peak value is obtained from the voltage-capacity curve; a maximum value of the peak voltage is determined; and the maximum value is taken as the high-voltage inflection point.

As shown in FIG. 3, there are two peak values obtained from the differential voltage-capacity curve, namely point A on the left and point B on the right. The peak voltage corresponding to point B in the voltage-capacity curve is greater than the peak voltage corresponding to point A in the voltage-capacity curve, so the peak voltage at point B is taken as the high-voltage inflection point (HVTP) of the battery, and the peak voltage at point A is taken as the low-voltage inflection point (LVTP) of the battery.

In an embodiment of the present disclosure, before updating the high-voltage inflection point capacity of the battery according to the initial residual capacity corresponding to the initial static voltage and the first capacity charged into the battery from the initial static voltage to the high-voltage inflection point, the method further includes:
S41. Obtaining the initial residual capacity.

In an embodiment of the present disclosure, the initial residual capacity may be obtained using Relaxation Voltage Correction (RVC). In an example, after obtaining the initial static voltage of the lithium iron phosphate lithium-ion battery, an initial residual capacity SOC_{low} corresponding to the initial static voltage is obtained by looking up a table of battery voltage versus state of charge (SOC).

In another embodiment of the present disclosure, the initial residual capacity SOC_{low} may also be obtained by a Kalman filtering method. The Kalman filtering method is a method of building an equivalent circuit model of resistors and capacitors, and then inputting real-time voltage values into the circuit model to predict the state of charge of a battery pack in real time under dynamic conditions. Therefore, by inputting the initial static voltage into this circuit model, the initial residual capacity SOC_{low} can be obtained. Since the accuracy may be higher in states where the voltage change is more apparent during discharge, when the voltage is below the low voltage inflection point, the Kalman filtering method can also predict the SOC state, and thus the initial residual capacity SOC low corresponding to the initial static voltage can be obtained using the Kalman filtering method, thereby obtaining the high-voltage inflection point capacity more accurately.
S42. Obtaining a previous maximum capacity of the battery.

In an embodiment of the present disclosure, a previous maximum capacity Qₗₐₛₜ of the lithium iron phosphate lithium-ion battery after the last update of the high-voltage inflection point capacity is obtained.
S43. Determining the current high-voltage inflection point capacity according to the previous maximum capacity, the initial residual capacity, and the first capacity.

In an embodiment of the present disclosure, the determining the current high-voltage inflection point capacity according to the previous maximum capacity, the initial residual capacity, and the first capacity includes:
S431. Calculating a product of the previous maximum capacity and the initial residual capacity;
S432. Calculating a first sum of the product and the first capacity;
S433. Taking the first sum as the current high-voltage inflection point capacity.

In an embodiment of the present disclosure, the following formula may be used to calculate the current high-voltage inflection point capacity:

Q_{HVTP}=Q_{soc}+SOC_{low}*Qₗₐₛₜ (2);
wherein, Q_{HVTP} represents the current high-voltage inflection point capacity, and Q_{soc} represents the first capacity.

In step S2, the current maximum capacity of the battery is determined according to the current high-voltage inflection point capacity.

In an embodiment of the present disclosure, the determining the current maximum capacity of the battery according to the current high-voltage inflection point capacity includes:
S21. Obtaining a second capacity charged into the battery from the high-voltage inflection point to full charge;
S22. Determining the current maximum capacity according to the second capacity and the current high-voltage inflection point capacity.

In an embodiment of the present disclosure, the following formula may be used to calculate the current maximum capacity of the lithium iron phosphate lithium-ion battery:

Qₘₐₓ=Q_{HVTP}+Q_{HVP} (3);
wherein, Qₘₐₓ represents the current maximum capacity, and Q_{HVP} represents the second capacity.

In an embodiment of the present disclosure, the method further includes:
S5. When the initial static voltage is greater than the preset voltage threshold, determining the current maximum capacity according to a previous high-voltage inflection point capacity of the battery.

In an embodiment of the present disclosure, when the initial static voltage is greater than the preset voltage threshold, the previously updated high-voltage inflection point capacity Q_{HVTP} is substituted into formula (3) to calculate the current maximum capacity of the battery.

In some aspects, the battery capacity determination method of the present disclosure can update the high-voltage inflection point capacity of the battery and determine the current maximum capacity of the battery according to the current high-voltage inflection point capacity, avoiding the problem of large errors in calculating battery capacity using offline battery data, thereby improving the accuracy of battery capacity.

A battery state-of-health determination method according to an embodiment of the present disclosure will be described below with reference to FIG. 4. The battery state-of-health determination method may include the following steps:
S61. A current maximum capacity of a battery is determined by a capacity determination method described above;
S62. A state-of-health of the battery is determined according to a ratio of the current maximum capacity to an initial capacity of the battery.

In an embodiment of the present disclosure, after obtaining the current maximum capacity of the battery using the battery capacity determination method, a ratio of the current maximum capacity to the initial capacity of the battery is calculated, and the battery state-of-health is determined according to the ratio.

In an embodiment of the present disclosure, the ratio may be converted into a percentage, and the percentage may be used as the battery state-of-health parameter. In an embodiment of the present disclosure, when the ratio of the current maximum capacity to the initial capacity of the battery is less than or equal to a preset threshold, notification information is sent to notify the user to replace or repair the battery.

In some aspects, the battery state-of-health determination method of the present disclosure can, after updating the high-voltage inflection point capacity of the battery, determine the current maximum capacity of the battery according to the updated high-voltage inflection point capacity, and further determine the state-of-health of the battery according to the current maximum capacity of the battery, which can improve the accuracy of the state-of-health.

After introducing the battery capacity determination method and the battery state-of-health determination method according to one or more embodiments of the present disclosure, a non-transitory computer-readable storage medium according to one or more embodiments of the present disclosure will be described with reference to FIG. 5. The non-transitory computer-readable storage medium may store instructions which, when executed by a processor, cause the processor to execute the battery capacity determination method or the battery state-of-health determination method. Referring to FIG. 5, a program product 500 (for example, a non-transitory computer-readable storage medium storing instructions) for implementing the above method according to an embodiment of the present disclosure is described, which may be in the form of a portable compact disc read-only memory (CD-ROM) and include program code, and may be run on a device, such as a personal computer. However, the program product of the present disclosure is not limited thereto; herein, a non-transitory computer-readable storage medium may be any tangible medium that contains or stores a program for use by or in connection with an instruction execution system, apparatus, or device.

The program product may employ any combination of one or more non-transitory computer-readable storage media. A non-transitory computer-readable storage medium may be, for example, but not limited to, an electrical, magnetic, optical, electromagnetic, infrared, or semiconductor system, apparatus, or device, or any combination thereof. Additional examples of non-transitory computer-readable storage media include: an electrical connection having one or more wires, a portable disk, a hard disk, random access memory (RAM), read-only memory (ROM), erasable programmable read-only memory (EPROM or flash memory), optical fiber, portable compact disc read-only memory (CD-ROM), an optical storage device, a magnetic storage device, or any suitable combination of the foregoing.

Computer program code for carrying out operations of the present disclosure may be written in any combination of one or more programming languages, including an object-oriented programming language such as Java or C++ and a procedural programming language such as the “C” programming language or a similar programming language. The program code may execute entirely on a user computing device, partly on a user computing device and partly on a remote computing device, or entirely on the remote computing device or server. In a scenario involving a remote computing device, the remote computing device may be connected to a user computing device through any type of network, including a local area network (LAN) or a wide area network (WAN), or may be connected to an external computing device (for example, through the Internet using an Internet Service Provider).

After introducing the computer program product according to one or more embodiments of the present disclosure, next, a processor according to one or more embodiments of the present disclosure will be described. The processor is configured to execute instructions to implement the battery capacity determination method or the battery state-of-health determination method. In an embodiment of the present disclosure, the processor may be a chip, an MCU, an integrated circuit, or a terminal device.

After introducing the processor according to one or more embodiments of the present disclosure, a power distribution box according to one or more embodiments of the present disclosure will be described. The power distribution box includes the processor, which is disposed within the power distribution box.

After introducing the power distribution box according to one or more embodiments of the present disclosure, a battery management system (BMS) according to one or more embodiments of the present disclosure will be described. The BMS system includes the power distribution box and/or the processor, and the power distribution box and/or the processor may be disposed within the BMS system.

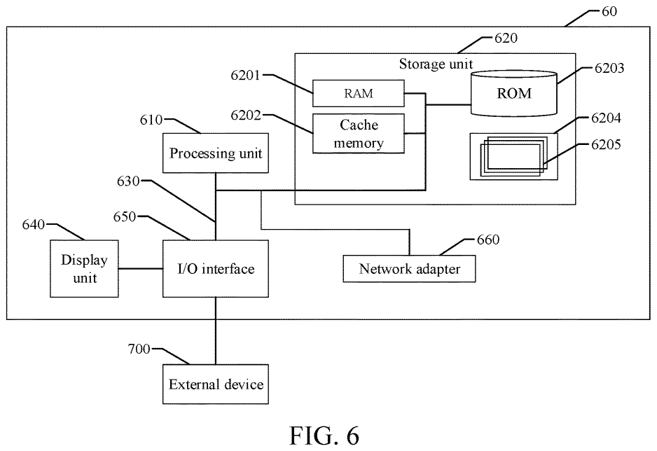

After introducing the BMS system according to one or more embodiments of the present disclosure, an electrical apparatus according to one or more embodiments of the present disclosure will be described with reference to FIG. 6. The electrical apparatus includes the BMS system, which is disposed within the electrical apparatus. The electrical apparatus may be a new energy vehicle, an aircraft, a ship, an energy storage cabinet, or another suitable apparatus.

The electrical apparatus 60 shown in FIG. 6 is merely an example and should not impose any limitations on the function and scope of use of one or more embodiments of the present disclosure.

As shown in FIG. 6, the electrical apparatus 60 is embodied in the form of a general-purpose computing device. Components of the electrical apparatus 60 may include, but are not limited to: at least one processing unit 610, at least one storage unit 620, a bus 630 connecting different system components (including the storage unit 620 and the processing unit 610), and a display unit 640. The storage unit stores program code which may be executed by the processing unit 610, causing the processing unit 610 to perform the steps according to one or more embodiments described in the present disclosure. For example, the processing unit 610 may execute step S1 and step S2 shown in FIG. 1, or step S61 and step S62 shown in FIG. 4.

The storage unit 620 may include a volatile storage unit, such as random access memory (RAM) 6201 and/or cache memory 6202, and may further include read-only memory (ROM) 6203. The storage unit 620 may also include a program/utility 6204 having a set (at least one) of program modules 6205, including but not limited to: an operating system, one or more application programs, other program modules, and program data, each or some combination of which may include an implementation of a network environment.

In some embodiments, a module, submodule, unit, or any combination thereof may be implemented by processing circuitry, software stored in memory and executed by processing circuitry, or a combination of processing circuitry and software. When implemented by software, the module, submodule, or unit may be stored as instructions or program code in a non-transitory computer-readable storage medium and executed by one or more processors or processing circuitry to perform one or more corresponding operations.

The bus 630 may include a data bus, an address bus, and a control bus.

The electrical apparatus 60 may also communicate with one or more external devices 70 (for example, a keyboard, a pointing device, a Bluetooth device, or another external device), and such communication may be via an input/output (I/O) interface 650. The electrical apparatus 60 also includes a display unit 640 connected to the input/output (I/O) interface 650 for display. Furthermore, the electrical apparatus 60 may also communicate with one or more networks (for example, a local area network (LAN), a wide area network (WAN), and/or a public network such as the Internet) via a network adapter 660. As shown, the network adapter 660 communicates with other modules of the electrical apparatus 60 via the bus 630. It should be understood that, although not shown in the figure, other hardware and/or software modules may be used in conjunction with the electrical apparatus 60, including but not limited to: microcode, device drivers, redundant processing units, external disk drive arrays, RAID systems, tape drives, data backup storage systems, or another suitable module.

Furthermore, although the operations of the method of the present disclosure are described in a particular order in the accompanying drawings, this does not require or imply that these operations need to be performed in that particular order, or that every shown operation needs to be performed to achieve desirable results. Additionally or alternatively, certain steps may be omitted, a plurality of steps may be combined into one step for execution, and/or one step may be decomposed into a plurality of steps for execution.

Although the spirit and principles of the present disclosure have been described with reference to several non-limiting embodiments, it should be understood that the present disclosure is not limited to the disclosed embodiments, and the division of various aspects does not mean that features in these aspects are prevented from being combined. In some aspects, such division is for convenience of description. The present disclosure is intended to cover various modifications and arrangements included within the spirit of the present disclosure.

What is claimed is:

1. A battery capacity determination method, comprising:
when an initial static voltage of a battery at which a charging operation starts is less than or equal to a preset voltage threshold value, determining a current high-voltage inflection point capacity of the battery based on an initial residual capacity corresponding to the initial static voltage and a first capacity corresponding to a charge transferred into the battery from the initial static voltage to a high-voltage inflection point during the charging operation; and
determining a current maximum capacity of the battery based on the current high-voltage inflection point capacity.

2. The method according to claim 1, wherein the determining the current high-voltage inflection point capacity of the battery comprises:
obtaining the initial residual capacity;
obtaining a previous maximum capacity of the battery; and
determining the current high-voltage inflection point capacity based on the previous maximum capacity, the initial residual capacity, and the first capacity.

3. The method according to claim 2, wherein determining the current high-voltage inflection point capacity based on the previous maximum capacity, the initial residual capacity, and the first capacity comprises:
calculating a product of the previous maximum capacity and the initial residual capacity; and
determining the current high-voltage inflection point capacity based on a sum of the product and the first capacity.

4. The method according to claim 1, wherein the determining the current maximum capacity of the battery comprises:
obtaining a second capacity corresponding to the charge transferred into the battery from the high-voltage inflection point to a full charge state based on the charging operation; and
determining the current maximum capacity based on the second capacity and the current high-voltage inflection point capacity.

5. The method according to claim 1, further comprising:
when the initial static voltage is greater than the preset voltage threshold, determining the current maximum capacity based on a previous high-voltage inflection point capacity of the battery.

6. The method according to claim 1, further comprising:
obtaining a voltage-capacity curve of the battery during the charging operation;
obtaining a filtered voltage-capacity curve by performing smoothing filtering on the voltage-capacity curve;
obtaining a differential voltage-capacity curve by performing a differential operation on the voltage-capacity curve; and
determining the high-voltage inflection point based on a peak value of the differential voltage-capacity curve.

7. The method according to claim 6, wherein determining the high-voltage inflection point based on the peak value comprises:
obtaining a peak voltage corresponding to the peak value from the voltage-capacity curve; and
determining a maximum value of the peak voltage as the high-voltage inflection point.

8. The method according to claim 1, further comprising:
determining a state-of-health of the battery based on a ratio of the current maximum capacity to an initial capacity of the battery.

9. A battery capacity determination apparatus, comprising:
processing circuitry configured to:
when an initial static voltage of a battery at which a charging operation starts is less than or equal to a preset voltage threshold value, determine a current high-voltage inflection point capacity of the battery based on an initial residual capacity corresponding to the initial static voltage and a first capacity corresponding to a charge transferred into the battery from the initial static voltage to a high-voltage inflection point during the charging operation; and
determine a current maximum capacity of the battery based on the current high-voltage inflection point capacity.

10. The apparatus according to claim 9, wherein the processing circuitry is configured to:
obtain the initial residual capacity;
obtain a previous maximum capacity of the battery; and
determine the current high-voltage inflection point capacity based on the previous maximum capacity, the initial residual capacity, and the first capacity.

11. The apparatus according to claim 10, wherein the processing circuitry is configured to:
calculate a product of the previous maximum capacity and the initial residual capacity; and
determine the current high-voltage inflection point capacity based on a sum of the product and the first capacity.

12. The apparatus according to claim 9, wherein the processing circuitry is configured to:
obtain a second capacity corresponding to the charge transferred into the battery from the high-voltage inflection point to a full charge state based on the charging operation; and
determine the current maximum capacity based on the second capacity and the current high-voltage inflection point capacity.

13. The apparatus according to claim 9, wherein the processing circuitry is configured to:
when the initial static voltage is greater than the preset voltage threshold, determine the current maximum capacity based on a previous high-voltage inflection point capacity of the battery.

14. The apparatus according to claim 9, wherein the processing circuitry is configured to:
obtain a voltage-capacity curve of the battery during the charging operation;
obtain a filtered voltage-capacity curve by performing smoothing filtering on the voltage-capacity curve;
obtain a differential voltage-capacity curve by performing a differential operation on the voltage-capacity curve; and
determine the high-voltage inflection point based on a peak value of the differential voltage-capacity curve.

15. The apparatus according to claim 14, wherein the processing circuitry is configured to:
obtain a peak voltage corresponding to the peak value from the voltage-capacity curve; and
determine a maximum value of the peak voltage as the high-voltage inflection point.

16. The apparatus according to claim 9, wherein the processing circuitry is configured to:
determine a state-of-health of the battery based on a ratio of the current maximum capacity to an initial capacity of the battery.

17. A non-transitory computer-readable storage medium storing instructions which, when executed by at least one processor, cause the at least one processor to perform a battery capacity determination method, the method comprising:
when an initial static voltage of a battery at which a charging operation starts is less than or equal to a preset voltage threshold value, determining a current high-voltage inflection point capacity of the battery based on an initial residual capacity corresponding to the initial static voltage and a first capacity corresponding to a charge transferred into the battery from the initial static voltage to the high-voltage inflection point during the charging operation; and
determining a current maximum capacity of the battery based on the current high-voltage inflection point capacity.

18. The non-transitory computer-readable storage medium according to claim 17, wherein the determining the current high-voltage inflection point capacity of the battery comprises:
obtaining the initial residual capacity;
obtaining a previous maximum capacity of the battery; and
determining the current high-voltage inflection point capacity based on the previous maximum capacity, the initial residual capacity, and the first capacity.

19. The non-transitory computer-readable storage medium according to claim 18, wherein determining the current high-voltage inflection point capacity based on the previous maximum capacity, the initial residual capacity, and the first capacity comprises:
calculating a product of the previous maximum capacity and the initial residual capacity; and
determining the current high-voltage inflection point capacity based on a sum of the product and the first capacity.

20. The non-transitory computer-readable storage medium according to claim 17, wherein the determining the current maximum capacity of the battery comprises:
obtaining a second capacity corresponding to the charge transferred into the battery from the high-voltage inflection point to a full charge state based on the charging operation; and
determining the current maximum capacity based on the second capacity and the current high-voltage inflection point capacity.
